(19) United States
(12) Patent Application Publication
(10) Pub. No.: US 2010/0200832 A1
(43) Pub. Date: Aug. 12, 2010

(54) RESISTANCE VARIABLE ELEMENT

(75) Inventors: Hiroyasu Kawano, Kawasaki (JP); Keiji Shono, Bunkyo-ku (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/708,211

(22) Filed: Feb. 18, 2010

Related U.S. Application Data
(63) Continuation of application No. PCT/JP2007/066247, filed on Aug. 22, 2007.

(51) Int. Cl. H01L 45/00

(52) U.S. Cl. 257/4; 257/E45.002

(57) ABSTRACT

A resistance variable device is provided, which is capable of making a bipolar operation based on a predetermined operation principle. The resistance variable device is usable as a storage device. The resistance variable device has a laminated structure which include, for example, a first electrode, a second electrode, and a hole conductive layer between the first and second electrodes. The hole conductive layer gives anions to the second electrode, thereby changing its state from a reference electric field state to a positive electric field state. The hole conductive layer also receives anions from the second electrode, thereby changing its state from the positive electric field state to the reference electric field state.

This application is a continuation of International Application No. PCT/JP2007/066247, filed on Aug. 22, 2007, the entire contents of which are incorporated herein by reference.

### TECHNICAL FIELD

The present invention relates to a resistance variable device capable of switching between a high resistance state of relatively low electrical conductivity to a low resistance state of relatively high electrical conductivity. The present invention also relates to a method of switching the resistance of such a resistance variable device.

### BACKGROUND ART

In the field of nonvolatile memory, ReRAMs (resistive RAMs) attract growing interest. A ReRAM is a resistance variable device, typically including a pair of electrodes and a recording film which is capable of selectively switching between a high resistance state and a low resistance state depending on the voltage applied across the electrodes. In a ReRAM, information recording and/or rewriting can be performed by utilizing the selective resistance switching of recording film. Examples of such a ReRAM or resistance variable device are described in Patent Documents 1-4 listed below.

Patent Document 1: Japanese Lain-open Patent Publication No. 2004-273615

Patent Document 2: Japanese Lain-open Patent Publication No. 2004-281913

Patent Document 3: Japanese Lain-open Patent Publication No. 2005-123361

Patent Document 4: Japanese Lain-open Patent Publication No. 2005-203463

ReRAM is divided roughly into two types, namely bipolar type and unipolar type, based on an electrical characteristic. In bipolar ReRAMs, the voltage application directions across the two electrodes are different for switching the recording film from the high resistance state to the low resistance state and for switching the recording film from the low resistance state to the high resistance state. In other words, the bipolar ReRAM uses different polarities of voltage for changing or switching between the two states of resistance. In unipolar ReRAMs, on the other hand, the voltage application direction across the electrodes is the same for switching the recording film from the high resistance state to the low resistance state and for switching the recording film from the low resistance state to the high resistance state. In other words, the unipolar ReRAM uses the same polarity of voltage for switching between the two states of resistance.

In general, bipolar ReRAMs can operate more quickly than unipolar ReRAMs. Examples of bipolar ReRAMs include one provided with a PrCaMnO₃ recording film, and one provided with a recording film of Cr-doped SrZrO₃. It is known that these ReRAMs can operate as a bipolar type, but their operation mechanism is still unknown. Under these circumstances, guiding principles cannot be established for optimizing the selection of material and design/dimension for each part of a ReRAM, and hence it is difficult or even impossible to optimize the overall design of the ReRAM. It should be noted here that the workings of ReRAMs are thought to be significantly different when primary materials used to constitute recording films are different.

The present invention has been proposed under the above-described circumstances. It is therefore an object of the present invention to provide a resistance variable device which is capable of operating as a bipolar type in accordance with a prescribed mechanism and which is usable as a storage device.

### DISCLOSURE OF THE INVENTION

A first aspect of the present invention provides a resistance variable device having a laminated structure. Specifically, the resistance variable device includes a first electrode, a second electrode, and a hole conductive layer disposed between the first electrode and the second electrode. The hole conductive layer gives anions to the second electrode for changing its state from a reference electric field state to a positive electric field state. The hole conductive layer also receives anions from the second electrode for changing from the positive electric field state to the reference electric field state. In this first aspect, the reference electric field state is a state where there is no, or essentially no internal electric field existing in the hole conductive layer. The positive electric field state is a state where there is a significant positive internal electric field existing in the hole conductive layer. The hole conductive layer is capable of reversibly changing its state between the reference electric field state and the positive electric field state.

With the above-described configuration, the resistance variable device can be selectively switched to a low resistance state where the hole conductive layer is in the reference electric field state or to a high resistance state where the hole conductive layer is in the positive electric field state.

With the resistance variable device being in the low resistance state, a predetermined voltage is applied, for a predetermined period of time, across the first and the second electrodes as a negative terminal and a positive terminal, respectively. Then, due to an electric field effect, anions are produced in the hole conductive layer, and moved from the hole conductive layer to the second electrode (in other words, the hole conductive layer gives anions to the second electrode). As a result, positive-charge vacancies occur and increase (accumulate) in the hole conductive layer, producing a positive internal electric field, which puts the hole conductive layer in a positive electric field state. Since the main carrier in the resistance variable device (provided with a hole conductive layer between two electrodes) is a hole, the positive internal electric field prevents holes from moving in the hole conductive layer. Accordingly, the hole conductive layer has a higher resistance when in the positive electric field state than in the reference electric field state (e.g. in a fieldless or zero field state). In this manner, the hole conductive layer changes from a low resistance state to a high resistance state, and hence causes the resistance variable device to switch from a low resistance state to a high resistance state (upward resistance change). Even after the voltage application is ceased, the hole conductive layer remains in the high resistance state, and hence the resistance variable device remains in the high resistance state.

With the resistance variable device being in the high resistance state (with the hole conductive layer being in the positive electric field state), a predetermined voltage is applied, for a predetermined period of time, across the first and the second electrodes as a positive terminal and a negative terminal, respectively. Then, due to an electric field effect, anions are produced in the second electrode, and moved from the second electrode to the hole conductive layer (in other words, anions are given from the second electrode to the hole conductive layer). As a result, the positive-charge vacancies in the hole conductive layer are electrically neutralized, and the internal electric field caused by the positive-charge vacancies essentially disappears. Thus, the hole conductive layer returns to the reference electric field state, assuming a decreased resistance value. In this manner, the hole conductive layer changes its state from the high resistance state to the low resistance state, the resistance variable device switches from the high resistance state to the low resistance state (downward resistance change). Even after the voltage application is ceased, the hole conductive layer remains in the low resistance state, and hence the resistance variable device remains in the low resistance state. The resistance variable device which assumes a low resistance state as described above can be switched again to a high resistance state by performing the above-described upward resistance changing process.

In the resistance variable device, the voltage application direction across the electrodes for switching the device from the low resistance state to the high resistance state is different from the voltage application direction across the electrodes for switching the device from the high resistance state to the low resistance state. With the resistance variable device, a bipolar operation enables resistance switching between a high resistance state of relatively low electrical conductivity and a low resistance state of relatively high electrical conductivity. Such resistance switching can be utilized for recording or rewriting information. In other words, the resistance variable device can be utilized as a nonvolatile storage device. Also, the resistance variable device can be utilized as a switching device for selectively changing the resistance at a predetermined point along a circuit.

Preferably, the hole conductive layer may be made of a binary substance containing a first element for producing anions and a second element capable of existing stably in two states of different valences (positive valences). Use of the second element, which is capable of existing stably in two states of different valences, is suitable for constituting a hole conductive layer capable of reversible switching between a reference electric field state and a positive electric field state. Use of a binary substance for constituting the hole conductive layer makes the resistance variable device suitable for manufacture by a C-MOS manufacturing process.

Preferably, the second element may be selected so that (rₘ−rₙ)/rₘ≦0.15 is satisfied, where rₘ is an ionic radius of an m-valence ion of the second element, and rₙ is an ionic radius of an n-valence ion of the second element (n>m).

Preferably, the hole conductive layer may be made of a p-type semiconducting oxide, and more preferably made of oxygen-defective Ti[+3, +4]O₂, oxygen-defective Cr₂[+2, +3]O₃, oxygen-defective Cr[+3, +4]O₂, oxygen-defective Mn[+3, +4]O₂, oxygen-defective Fe₂[+2, +3]O₃, oxygen-defective Co₂[+2, +3]O₃, oxygen-defective Zn[+2, +4]O₂, oxygen-defective Ru[+3, +4]O₂, oxygen-defective Ru₂[+4, +5]O₃, oxygen-defective Pd₂[+2, +3]O₃, oxygen-defective Ta[+3, +4]O₂, oxygen-defective Ta₂[+4, +5]O₅ or oxygen-defective Ce[+3, +4]O₂.

A second aspect of the present invention provides a resistance variable device having a laminated structure which includes: a first electrode; a second electrode; and an electron conductive layer between the first electrode and the second electrode. The electron conductive layer gives cations to the second electrode for changing its state from a reference electric field state to a negative electric field state. The electron conductive layer also receives cations from the second electrode for changing its state from the negative electric field state to the reference electric field state. The reference electric field state in the second aspect is a state where there is no, or essentially no, internal electric field existing in the electron conductive layer. The negative electric field state is a state where there is a significant negative internal electric field existing in the electron conductive layer. The electron conductive layer is capable of changing its state reversibly between the reference electric field state and the negative electric field state.

The resistance variable device which has the above-described configuration is capable of switching between a low resistance state where the electron conductive layer is in the reference electric field state and a high resistance state where the electron conductive layer is in the negative electric field state.

With the resistance variable device being in the reference electric field state, a predetermined voltage is applied, for a predetermined period of time, across the first and the second electrodes as a positive terminal and a negative terminal, respectively. Then, due to an electric field effect, cations are produced in the electron conductive layer, and moved from the electron conductive layer to the second electrode (in other words, cations are given from the electron conductive layer to the second electrode). As a result, negative-charge vacancies occur and increase (accumulate) in the electron conductive layer, producing a negative internal electric field, which puts the electron conductive layer in a negative electric field state. Since the main carrier in the resistance variable device (provided with an electron conductive layer between two electrodes) is an electron, the negative internal electric field prevents electrons from moving in the electron conductive layer. Accordingly, the electron conductive layer has a higher resistance when in the negative electric field state than in the reference electric field state (e.g. in a fieldless or zero field state). In this manner, the electron conductive layer changes from a low resistance state to a high resistance state, and hence causes the resistance variable device to switch from a low resistance state to a high resistance state (upward resistance change). Even after the voltage application is ceased, the electron conductive layer remains in the high resistance state, and hence the resistance variable device remains in the high resistance state.

With the resistance variable device being in the high resistance state, a predetermined voltage is applied, for a predetermined period of time, across the first and the second electrodes as a negative terminal and a positive terminal, respectively. Then, due to an electric field effect, cations are produced in the second electrode, and moved from the second electrode to the electrode conductive layer (in other words, cations are given from the second electrode to the electron conductive layer). As a result, the negative-charge vacancies in the electron conductive layer are electrically neutralized, and the internal electric field caused by the negative-charge vacancies essentially disappears. Thus, the electron conductive layer returns to the reference electric field state, assuming a decreased resistance value. In this manner, the electrode conductive layer changes its state from the high resistance state to the low resistance state, the resistance variable device switches from the high resistance state to the low resistance state (downward resistance change). Even after the voltage application is ceased, the electron conductive layer remains in the low resistance state, and hence the resistance variable device remains in the low resistance state. The resistance variable device which assumes a low resistance state as described above can be switched again to a high resistance state by performing the above-described upward resistance changing process.

In the resistance variable device, the voltage application direction across the electrodes for switching the device from the low resistance state to the high resistance state is different from the voltage application direction for switching the device from the high resistance state to the low resistance state. With the resistance variable device, a bipolar operation enables resistance switching between a high resistance state of relatively low electrical conductivity and a low resistance state of relatively high electrical conductivity. Such resistance switching can be utilized for recording or rewriting information. In other words, the resistance variable device can be utilized as a nonvolatile storage device. Also, the resistance variable device can be utilized as a switching device for selectively changing the resistance at a predetermined point along a circuit.

Preferably, the electron conductive layer may be made of a binary substance containing a first element for producing cations and a second element capable of existing stably in two states of different valences (negative valences). In this case, preferably, (rₘ−rₙ)/rₘ≦0.15 is satisfied, where rₘ is an ionic radius of an m-valence ion of the second element, and rₙ is an ionic radius of an n-valence ion of the second element (n>m). Also, preferably, the electron conductive layer is provided by silver-defective Ag₂S, silver-defective AgI or silver-defective AgBr.

### BRIEF DESCRIPTION OF THE DRAWINGS

FIG. 1 is a sectional view of a resistance variable device according to a first embodiment of the present invention.

FIG. 2 is a table listing examples of second chemical elements which can exist stably in two states of different valences.

FIG. 3 illustrates how the resistance variable device in FIG. 1 operates.

FIG. 4 is a sectional view of a resistance variable device according to a second embodiment of the present invention.

FIG. 5 illustrates how the resistance variable device in FIG. 4 operates.

FIG. 6 illustrates a laminated constitution of a sample device.

FIG. 7 is a graph which illustrates the result of resistance measurements made on the sample device.

### BEST MODE FOR CARRYING OUT THE INVENTION

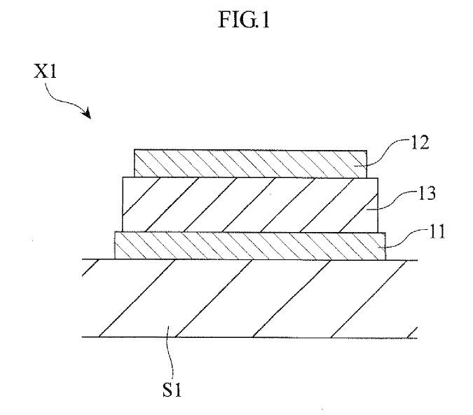

FIG. 1 is a sectional view of a resistance variable device X1 according to a first embodiment of the present invention. The resistance variable device X1 has a laminated structure which includes a substrate S1, a pair of electrodes 11, 12, and a hole conductive layer 13. The resistance variable device X1 is configured to switch between two states: a high resistance state of relatively low electrical conductivity and a low resistance state of relatively high electrical conductivity.

The substrate S1 is provided by e.g. a silicon substrate or an oxide substrate. The surface of the silicon substrate may be formed with a thermally grown oxide film. Examples of the oxide substrate include an MgO substrate, an SrTiO₃ substrate, an Al₂O₃ substrate, a quartz substrate and a glass substrate.

The electrode 11 is made of a highly electroconductive material, such as a precious metal. The precious metal may be Pt, Au, Pd, Ru and Ir. The electrode 11 has a thickness of e.g. 10 through 100 nm.

The electrode 12 is made of e.g. a highly electroconductive oxide. Examples of the highly electroconductive oxide may include SrRuO₃, RuO₂, IrO₂, SnO₂, ZnO and ITO. Alternatively, the electrode 12 may be made of an oxidative metal. Examples of such a metal include Ti, Ta, Al and Cr. The electrode 12 has a thickness of e.g. 50 through 200 nm.

The hole conductive layer 13 is disposed between the two electrodes 11 and 12. The hole conductive layer 13 is capable of changing its state from a reference electric field state to a positive electric field state by of giving anions to the electrode 12. The hole conductive layer 13 is also capable of changing its state from the positive electric field state to the reference electric field state by receiving anions from the electrode 12. The reference electric field state is a state where there is no, or essentially no, internal electric field existing in the hole conductive layer 13. The positive electric field state is a state where there is a significant positive internal electric field existing in the hole conductive layer 13. The hole conductive layer 13 is capable of changing its state reversibly between the reference electric field state and the positive electric field state.

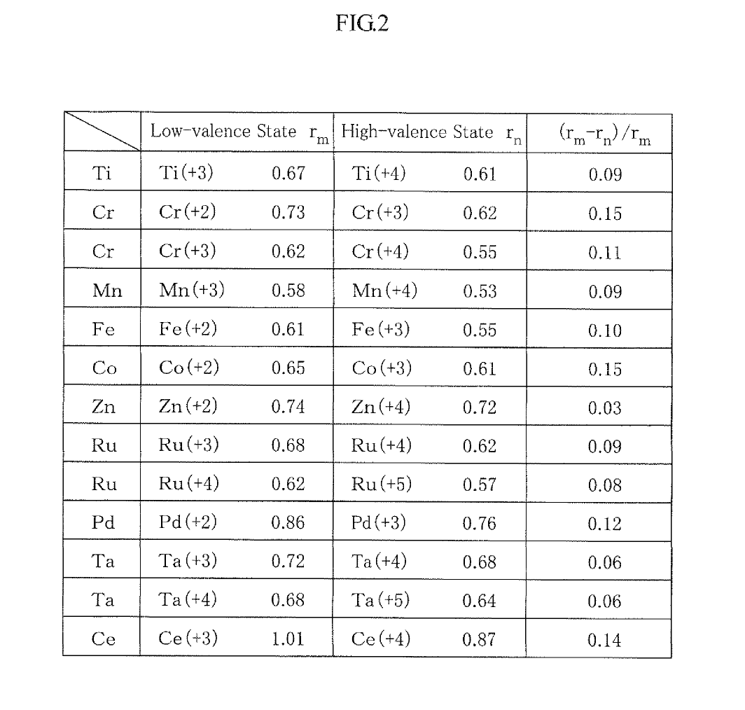

In the present embodiment, the hole conductive layer 13 is made of a binary hole conductive substance constituted by a first chemical element which is capable of providing anions and a second chemical element which is capable of existing stably in two states of different (positive) valences (low-valence state and high-valence state) (The binary substance includes a greater amount of the low-valence state second element than the high-valence state second element). An example of the first chemical element is oxygen. Examples of the second chemical element include titanium, chromium, manganese, iron, cobalt, zinc, ruthenium, palladium, tantalum and selenium. Usable second chemical elements are listed in the table in FIG. 2. Where the second chemical element has an m-valence ion which has an ionic radius rₘ, and an n-valence (n>m) ion which has an ionic radius rₙ, it is preferable that the second chemical element satisfies the following condition: (rₘ−rₙ)/rₘ≦0.15. When rₘ and rₙ satisfy this conditional expression, the second chemical element's two states of different valences (low-valence state and high-valence state) can exist more stably.

The hole conductive layer 13 as described is provided by e.g. a p-type semiconducting oxide. More specifically, the hole conductive layer 13 is provided by oxygen-defective Ti[+3,+4]O₂, oxygen-defective Cr₂[+2,+3]O₃, oxygen-defective Cr[+3,+4]O₂, oxygen-defective Mn[+3,+4]O₂, oxygen-defective Fe₂[+2,+3]O₃, oxygen-defective Co₂[+2,+3]O₃, oxygen-defective Zn[+2,+4]O₂, oxygen-defective Ru[+3,+4]O₂, oxygen-defective Ru₂[+4,+5]O₅, oxygen-defective Pd₂[+2,+3]O₃, oxygen-defective Ta[+3,+4]O₂, oxygen-defective Ta₂[+4,+5]O₅ or oxygen-defective Ce[+3,+4]O₂ (each containing a grater amount of the low-valence-state second chemical element than the high-valence state second chemical element). The hole conductive layer 13 has a thickness of e.g. 20 through 200 nm.

When manufacturing the resistance variable device X1 which has the above-described construction, first, formation of the electrode 11 is performed on the substrate S1. Specifically, a film of a predetermined material is formed on the substrate S1, and then etching is performed to the film through a predetermined resist pattern as a mask. Using such a procedure, the electrode 11 can be formed on the substrate S1 by means of a pattern formation technique. The film formation may be performed through a sputtering method, vacuum deposition method, CVD method or LD (Laser Deposition) method. Formation of the hole conductive layer 13 and the electrode 12 to be performed later can also be accomplished by using the same method of forming a film of a material and patterning by subsequent etching.

If the electrode 11 is made of Pt, a sputtering method can be used to form a film of Pt, using Ar gas as a sputtering gas and Pt as a target.

If the hole conductive layer 13 is formed from an oxygen-defective Ti[+3,+4]O₂ material, a formation method may be first employing a sputtering method to form a film of TiO₂, and then reducing the TiO₂ film with hydrogen, to obtain an oxygen-defective TiO₂ film of a predetermined oxygen deficiency level. Alternatively, a reactive sputtering method may be employed with a sputtering gas provided by a mixture of Ar and O₂ with a Ti target, to form an oxygen-defective TiO₂ film of a predetermined oxygen deficiency level. Alternatively, a reduction sputtering method may be employed with a sputtering gas provided by Ar, with a TiO₂ target, to form an oxygen-defective TiO₂ film of a predetermined oxygen deficiency level (This oxygen-defective

TiO₂ contains a greater amount of +3 valence Ti than +4 valence Ti). Next, the oxygen-defective TiO₂ film formed as the above is oxidized to a predetermined extent (in order to transform part of +3 valence Ti to +4 valence Ti within the oxidized region). The oxidization of the oxygen-defective TiO₂ film to the predetermined oxidization level can be accomplished by e.g. heating for a predetermined amount of time within an oxygen ambient provided by oxygen flow or oxygen substitution. In this process, the oxidization may be made only to an exposed surface of the hole conductive layer 13 (a surface of the hole conductive layer 13 which is to make contact with the electrode 12).

If the electrode 12 is made of an SrRuO₃ material, a sputtering method may be used with a mixture of Ar and O₂ as a sputtering gas and SrRuO₃ as a target, to form an SrRuO₃ film. If the electrode 12 is made of an oxidative metal (e.g. Ti, Ta, Al or Cr), a sputtering method may be used with Ar as a sputtering gas and the predetermined oxidative metal as a target, to form an oxidative metal film.

By forming the electrode 11, the hole conductive layer 13 and the electrode 12 as has been described above successively on the substrate S1, a resistance variable device X1 is manufactured.

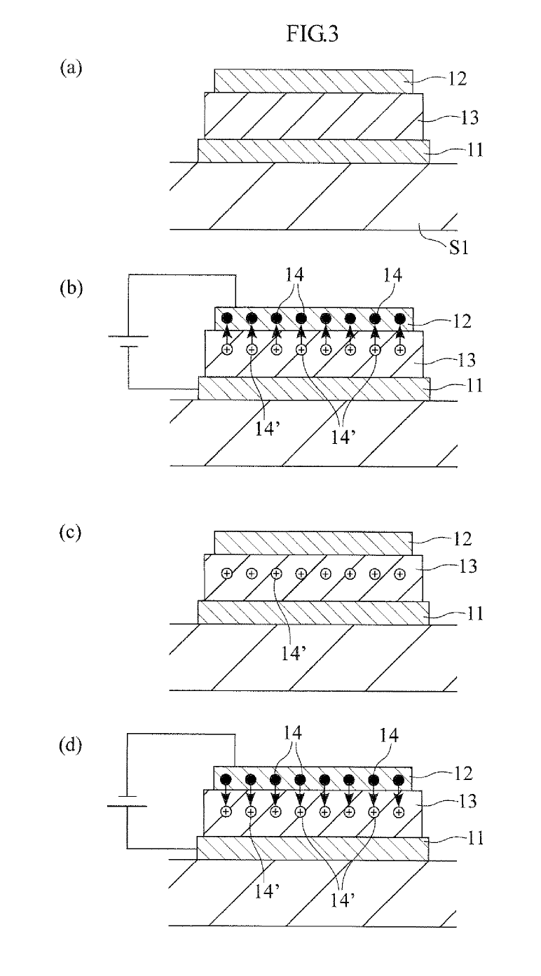

FIG. 3 illustrates how the resistance variable device X1 operates. The hole conductive layer 13 of the resistance variable device X1 is made of the first chemical element serving as a source of anions and the second chemical element capable of existing stably in two states of different valences (positive valences). In the initial state of a newly produced resistance variable device X1 as illustrated in FIG. 3(a), the hole conductive layer 13 has not yet released anions from the first chemical element, and so has not yet had an internal electric field which will appear as a consequence of releasing anions and the resulting positive-charge vacancies. In other words, the hole conductive layer is in a fieldless state where there is no electric field. When the hole conductive layer 13 is made of an oxygen-defective Ti[+3,+4]O₂, the hole conductive layer 13 is made of oxygen (the first chemical element) serving as a source of oxygen ion, and titanium (the second chemical element) which exists stably in a 3-valence state and a 4-valence state. In the initial state of a newly produced resistance variable device X1 as illustrated in FIG. 3(a), the hole conductive layer 13 has not yet released oxygen ions (anions 14), and so has not yet had an internal electric field which will appear as a consequence of releasing oxygen ions and the resulting positive-charge vacancies. In other words, the hole conductive layer is in a fieldless state (reference electric field state). In the resistance variable device X1 which includes the hole conductive layer 13 between the two electrodes 11 and 12, the main carrier is a hole. In the fieldless hole conductive layer 13, holes can easily move. Thus, in the initial state, the resistance variable device X1 is in a low resistance state. When in the low resistance state, the resistance of the resistance variable device X1 is 10 through 50 kΩ, for example.

With the resistance variable device X1 in the low resistance state, the application of a predetermined voltage for a predetermined period of time is performed across the electrodes 11, 12, using the electrodes 11 and 12 as a negative terminal and a positive terminal, respectively. Then, due to the effect of an electric field, as illustrated in FIG. 3(b), anions 14 (from the first chemical element) are produced in the hole conductive layer 13, and these anions 14 move from the hole conductive layer 13 to the electrode 12. As a result, as illustrated in FIG. 3(c), positive-charge vacancies 14′ accumulate in the hole conductive layer 13, giving rise to a positive internal electric field, which puts the hole conductive layer 13 in a positive electric field state. The second chemical element contained in the hole conductive layer 13 is capable of existing stably in two states of different valences (low-valence state and high-valence state). In the process of changing to the positive electric field state, the appearance of the positive-charge vacancies 14′ causes part of the second chemical elements in the hole conductive layer 13 to transition from the high-valence state to the low-valence state (electrons necessary for the valence change are supplied from the negative electrode 11 to the hole conductive layer 13), whereby partial charge compensation (electrical neutralization of the positive-charge vacancies 14′) is made. This alleviates the energy increase caused by the appearance of positive-charge vacancies 14′, and the hole conductive layer 13 maintains its material structure, which would otherwise be altered or destroyed by excess energy from the positive-charge vacancies 14′. Accordingly, the hole conductive layer 13 can be reversibly brought into a positive electric field state. When the hole conductive layer 13 is made of oxygen-defective Ti[+3,+4]O₂, with the resistance variable device X1 in the low resistance state, the application of a predetermined voltage for a predetermined period of time is performed across the electrodes 11, 12, using the electrodes 11 and 12 as a negative terminal and a positive terminal, respectively. Then, due to the effect of an electric field, as illustrated in FIG. 3(b), oxygen ions (anions 14) are produced in the hole conductive layer 13, and these oxygen ions move from the hole conductive layer 13 to the electrode 12. As a result, as illustrated in FIG. 3(c), positive-charge vacancies 14′ accumulate in the hole conductive layer 13, giving rise to a positive internal electric field, which puts the hole conductive layer 13 in a positive electric field state. The positive internal electric field prevents the holes from moving in the hole conductive layer 13, whereby the hole conductive layer 13 in the positive electric field state has a higher resistance than when it is in the reference electric field state (fieldless state, for example). Through the above-described process in which the hole conductive layer 13 changes its state from a low resistance state to a high resistance state, the resistance variable device X1 switches from a low resistance state to a high resistance state (upward resistance change). Even after the voltage application is ceased, the hole conductive layer 13 remains in the high resistance state, and hence the resistance variable device X1 remains in the high resistance state. In the high resistance state, the resistance variable device X1 has a resistance of e.g. 200 through 250 kΩ. The upward resistance change requires a minimum voltage of e.g. +2 through +5 volts (positive voltage means that the electric potential of the electrode 12 is higher than that of the electrode 11).

With the resistance variable device X1 in the high resistance state, the application of a predetermined voltage for a predetermined period of time is performed across the electrodes 11, 12, using the electrodes 11 and 12 as a positive terminal and a negative terminal, respectively. Due to the effect of an electric field, as illustrated in FIG. 3(d), anions 14 are produced in the electrode 12. As these anions 14 move from the electrode 12 to the hole conductive layer 13, the positive-charge vacancies 14′ in the hole conductive layer 13 are electrically neutralized, and the internal electric field caused by the positive-charge vacancies 14′ disappears essentially as illustrated in FIG. 3(a), whereby the hole conductive layer 13 returns to the reference electric field state. The hole conductive layer 13 contains the second chemical element which is capable of existing stably in two states of different valences (low-valence state and high-valence state). In the process of returning to the reference electric field state, disappearance of the positive-charge vacancies 14′ is accompanied by disappearance of the charge compensation effect, and part of the second chemical element in the hole conductive layer 13 make transition from the low-valence state to the high-valence state. This maintains electrically neutral state in the hole conductive layer 13, and the hole conductive layer 13 now is allowed to return to the reference electric field state, reversibly. By returning to the reference electric field state, the hole conductive layer 13 now has a decreased resistance value. Thus, as the hole conductive layer 13 changes its state from the high resistance state to the low resistance state, the resistance variable device X1 switches from the high resistance state to the low resistance state (downward resistance change). Even after the voltage application is ceased, the hole conductive layer 13 remains in the low resistance state, and hence the resistance variable device X1 remains in the low resistance state. The resistance variable device X1 which assumes a low resistance state as described above can be switched again to a high resistance state by performing the above-described upward resistance changing process.

As has been described above, the resistance variable device X1 is capable of selectively switching between a low resistance state in which the hole conductive layer 13 assumes the reference electric field state, and a high resistance state in which the hole conductive layer 13 assumes a positive electric field state.

In the resistance variable device X1, the voltage application direction across the electrodes 11, 12 for switching from the low resistance state to the high resistance state is different from the voltage application direction across the electrodes 11, 12 for switching from the high resistance state to the low resistance state. The resistance variable device X1 is capable of making a bipolar type resistance switching between a high resistance state of relatively low electrical conductivity and a low resistance state of relatively high electrical conductivity. Such resistance switching can be utilized for information recording or information rewriting. In other words, the resistance variable device X1 can be utilized as a resistance variable nonvolatile storage device. Also, the resistance variable device can be utilized as a switching device for selectively changing the resistance at a predetermined place in a circuit.

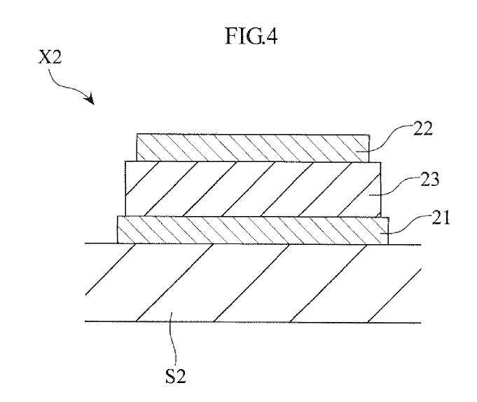

FIG. 4 is a sectional view of a resistance variable device X2 according to a second embodiment of the present invention. The resistance variable device X2 has a laminated structure which includes a substrate S2, a pair of electrodes 21, 22, and an electron conductive layer 23, and is capable of switching between a high resistance state of relatively low electrical conductivity and a low resistance state of relatively high electrical conductivity.

The substrate S2 is provided by e.g. a silicon substrate or an oxide substrate. The silicon substrate may have a surface formed with a thermally grown oxide film.

The electrode 21 is provided by e.g. an electrically conductive oxide or an electrically conductive nitride, which does not easily form an alloy with metal cations. Examples of such an electrically conductive oxide include SrRuO₃, ZnO, SnO and ITO. Examples of such an electrically conductive nitride include TiN and TaN. The electrode 21 has a thickness of e.g. 10 through 100 nm.

The electrode 22 is made of a metal which has a good solid solubility for metal cation and also has a high electromigration resistance. Examples of such a metal include Pt, Au, Pd, Ru and Cu. The electrode 22 has a thickness of e.g. 50 through 200 nm.

The electron conductive layer 23, which is between the electrodes 21, 22, is capable of giving cations to the electrode 22 thereby changing its state from a reference electric field state to a negative electric field state, as well as capable of receiving cations from the electrode 22 thereby changing its state from the negative electric field state to the reference electric field state. The reference electric field state is a state where there is no, or essentially no internal electric field existing in the electron conductive layer 23. The negative electric field state is a state where there is a significant, negative internal electric field existing in the electron conductive layer 23. The electron conductive layer 23 is capable of changing its state reversibly between the reference electric field state and the negative electric field state.

In the present embodiment, the electron conductive layer is made of a binary electron conductive substance constituted by a first chemical element which is capable of providing cations and a second chemical element which is capable of existing stably in two states of different (negative) valences (low-valence state and high-valence state) (The binary substance contains a greater amount of low-valence-state second elements having a smaller absolute value in the valence number than high-valence-state second elements having a greater absolute value in the valence number). An example of the first chemical element is silver. Examples of the second chemical element include sulfur, iodine and bromine. Where the second chemical element has an m-valence ion which has an ionic radius rₘ, and an n-valence (n>m) ion which has an ionic radius rₙ, it is preferable that the second chemical element satisfies (rₘ−rₙ)/rₘ≦0.15. When rₘ and rₙ satisfy this, the second chemical element's two states of different valences (low-valence state and high-valence state) can exist stably.

The electron conductive layer 23 as described is provided by e.g. silver-defective Ag₂S, silver-defective AgI and silver-defective AgBr. In these silver-defective materials, the second chemical element which is provided by e.g. S, I, and Br each contains a greater amount of low-valence-state elements of a smaller absolute value in the valence number than high-valence-state elements of a greater absolute value in the valence number. Specifically, silver-defective Ag₂S contains more −(2−x) valence sulfur than −2 valence sulfur. Likewise, silver-defective AgI contains more −(1−x) valence iodine than −1 valence iodine, and silver-defective AgBr contains more −(1−x) bromine than −1 valence bromine. The electron conductive layer 23 has a thickness of e.g. 20 through 200 nm.

When manufacturing the resistance variable device X2 which has the above-described construction, first, the electrode 21 is formed on the substrate S2. Specifically, a film of a predetermined material is formed on the substrate S2, and then etching is performed to the film through a predetermined resist pattern as a mask. By such a patterning procedure, the electrode 21 can be formed on the substrate S2. The film formation may be performed by a sputtering method, vacuum deposition method, CVD method or LD method. Formation of the electron conductive layer 23 and the electrode 22 to be performed later can also be accomplished by using the same method of forming a film of a material and patterning by subsequent etching.

When the electrode 21 is to be made of SrRuO₃, a sputtering method may be performed, with the use of a mixture of Ar and O₂ as a sputtering gas and an SrRuO₃ as a target for forming an SrRuO₃ film.

When the electron conductive layer 23 is to be made of a silver-defective Ag₂S, a formation method may be first employing a sputtering method of using Ar as a sputtering gas and the silver-defective Ag₂S as a target, to form a film of silver-defective Ag₂S which has a predetermined silver deficiency level. (This silver-defective Ag₂S contains a greater amount −(2−x) valence sulfur than −2 valence sulfur). Then, the obtained silver-defective Ag₂S film may be doped with Ag ions (thereby transforming a part of −(2−x) valence S to −2 valence S).

When the electrode 22 is to be made of Pt, a sputtering method may be performed, with the use of Ar as a sputtering gas and Pt as a target for forming a Pt film on the electron conductive layer 23.

By forming the electrode 21, the electron conductive layer 23, and the electrode 22 as has been described above successively on the substrate S2, a resistance variable device X2 is manufactured.

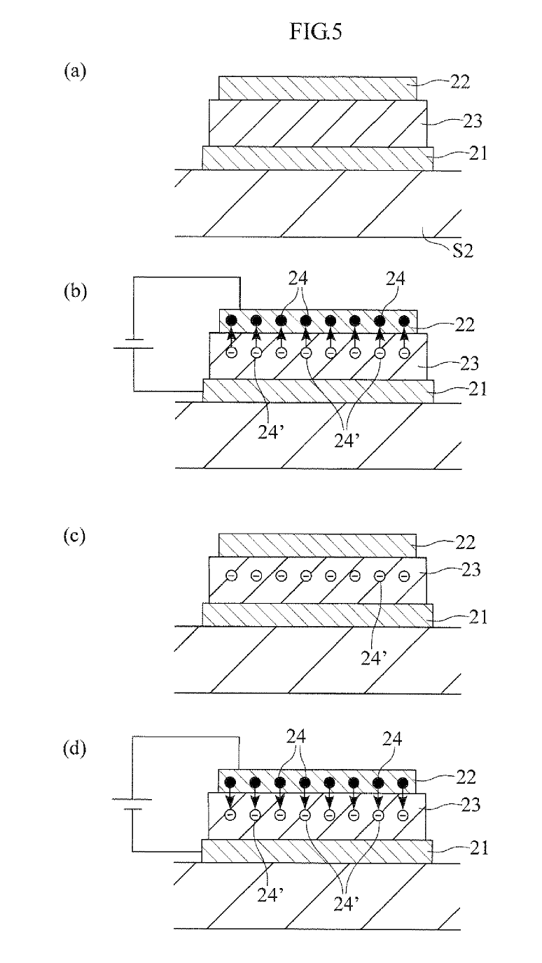

FIG. 5 illustrates how the resistance variable device X2 operates. The electron conductive layer 23 of the resistance variable device X2 is made of the first chemical element which serves as a source of cations and the second chemical element which is capable of existing stably in two states of different valences (negative valences). In an initial state, i.e. as manufactured state, of the resistance variable device X2 as illustrated in FIG. 5(a), the electron conductive layer 23 has not yet released the cations from the first chemical element, and so has not yet had an internal electric field which will appear as a consequence of providing the cations and resulting negative-charge vacancies; in other words, the hole conductive layer is in a fieldless state where there is no electric field. Where the electron conductive layer 23 is made of silver-defective Ag₂S, the electron conductive layer is made of silver (the first chemical element) which serves as the source of silver ions, and sulfur (the second chemical element) existing stably in the high-valence state which is −2 valence state and in the low-valence state which is −(2−x) valence state. In its initial state, i.e. as manufactured state, of the resistance variable device X2 as illustrated in FIG. 5(a), the electron conductive layer 23 has not yet released silver ions (cations 24), and so has not yet had an internal electric field which will appear as a consequence of providing the silver ions; in other words, the hole conductive layer is in a fieldless state (reference electric field state). In the resistance variable device X2 which includes the electron conductive layer 23 between the two electrodes 21, 22, electrons are the main carrier. The electrons can easily move in the fieldless electron conductive layer 23, and hence the resistance variable device X2 in the initial state is in a low resistance state. In the low resistance state, the resistance variable device X2 has a resistance of e.g. 1 through 5 kΩ.

With the resistance variable device X2 in the low resistance state, an application of a predetermined voltage for a predetermined period of time is performed across the electrodes 21, 22, using the electrodes 21 and 22 as a positive terminal and a negative terminal, respectively. This causes, due to an electric field effect, generation of cations 24 (from the first chemical element) in the electron conductive layer 23, as illustrated in FIG. 5(b), and moves the cations 24 from the electron conductive layer 23 to the electrode 22. As a result, negative-charge vacancies 24′ accumulate, as illustrated in FIG. 5(c), in the electron conductive layer 23, giving rise to a negative internal electric field, which puts the electron conductive layer 23 in a negative electric field state. The electron conductive layer 23 contains the second chemical element which is capable of existing stably in two states of different valences (low-valence state and high-valence state). In the process of state change to the negative electric field, appearance of the negative-charge vacancies 24′ is accompanied by partial charge compensation (electrical neutralization of the negative-charge vacancies 24′) by part of the second chemical element in the electron conductive layer 23 which makes transition from the high-valence state to the low-valence state (in this process the electron conductive layer 23 releases unnecessary electrons to the electrode 21). This reduces the energy increase caused by the negative-charge vacancies 24′. Thus, the electron conductive layer 23 maintains its material structure which may otherwise be altered or destroyed by the excess energy caused by negative-charge vacancies 24′, and the electron conductive layer 23 can attain a negative electric field state reversibly. In an instance where the electron conductive layer 23 is made of silver-defective Ag₂S, an application of a predetermined voltage for a predetermined period of time is performed across the electrodes 21, 22, using the electrodes 21 and 22 as the positive terminal and the negative terminal, respectively. This causes, due to an electric field effect, generation of silver ions (cations 24) in the electron conductive layer 23, as illustrated in FIG. 5(b), and moves silver ions move from the electron conductive layer 23 to the electrode 22. As a result, negative-charge vacancies 24′ accumulate, as illustrated in FIG. 5(c), in the electron conductive layer 23, giving rise to a negative internal electric field, which puts the electron conductive layer 23 in a negative electric field state. The negative internal electric field tens to prevent the electrons from moving in the electron conductive layer 23, and for this reason the electron conductive layer 23 has a higher resistance value when it is in the negative electric field state than when the electron conductive layer 23 is in the reference electric field state (fieldless state, for example). Through the above-described process in which the electron conductive layer 23 changes its state from a low resistance state to a high resistance state, the resistance variable device X2 switches from a low resistance state to a high resistance state (upward resistance change). Even after the voltage application is ceased, the electron conductive layer 23 remains in the high resistance state, and hence the resistance variable device X2 remains in the high resistance state. In the high resistance state, the resistance variable device X2 has a resistance of e.g. 20 through 30 kΩ. The upward resistance change requires a minimum voltage of e.g. −4 through −6 volts (positive voltage means a case where the electrode 22 has a higher potential than the electrode 21).

With the resistance variable device X2 in the high resistance state, an application of a predetermined voltage for a predetermined period of time is performed across the electrodes 21, 22, using the electrodes 21 and 22 as a negative terminal and a positive terminal, respectively.

This causes, due to an electric field effect, generation of cations 24 in the electrode 22, as illustrated in FIG. 5(d), and moves cations 24 move from the electrode 22 to the electron conductive layer 23. Thus, the negative-charge vacancies 24′ in the electron conductive layer 23 are electrically neutralized, and the internal electric field caused by the negative-charge vacancies 24′ disappears essentially as illustrated in FIG. 5(a), whereby the electron conductive layer 23 returns to the reference electric field state. The electron conductive layer 23 contains the second chemical element which is capable of existing stably in two states of different valences (low-valence state and high-valence state). In the process of returning to the reference electric field state, disappearance of the negative-charge vacancies 24′ is accompanied by disappearance of the charge compensation effect through the transition of part of the second chemical element, contained in the electron conductive layer 23, from the low-valence state to the high-valence state. This maintains electrically neutral state in the electron conductive layer 23, and the electron conductive layer 23 can return to the reference electric field state reversibly. By returning to the reference electric field state, the electron conductive layer 23 has a decreased resistance value. Thus, as the electron conductive layer 23 changes its state from the high resistance state to the low resistance state, the resistance variable device X2 switches from the high resistance state to the low resistance state (downward resistance change). Even after the voltage application is ceased, the electron conductive layer 23 remains in the low resistance state, and hence the resistance variable device X2 remains in the low resistance state. A resistance variable device X2 which assumes a low resistance state as described above can be switched again to a high resistance state by performing the above-described upward resistance changing process.

As described above, the resistance variable device X2 is capable of selectively switching between a low resistance state in which the electron conductive layer 23 assumes the reference electric field state, and a high resistance state in which the electron conductive layer 23 assumes a positive electric field state.

In the resistance variable device X2, the voltage application direction across the electrodes 21, 22 for switching from the low resistance state to the high resistance state is different from the voltage application direction across the electrodes 21, 22 for switching from the high resistance state to the low resistance state. The resistance variable device X2 is capable of making a bipolar type resistance switching between a high resistance state of relatively low electrical conductivity and a low resistance state of relatively high electrical conductivity. Such resistance switching can be utilized for information recording or information rewriting. In other words, the resistance variable device X2 can be utilized as a resistance variable nonvolatile storage device. Also, the resistance variable device can be utilized as a switching device for selectively changing the resistance at a predetermined place in a circuit.

### EXAMPLES

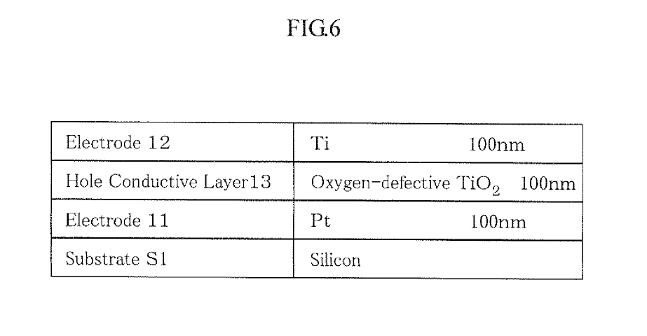

A sample device which has a laminated constitution illustrated in FIG. 6 was produced as the resistance variable device X1. The sample device has a hole conductive layer 3 made of oxygen-defective Ti[+3, +4]O₂. In its initial state, the sample device was in a low resistance state, with a resistance value of 13 kΩ. The resistance measurement was performed as follows: The electrode 11 was used as a negative electrode, and the electrode 12 was used as a positive electrode. A voltage of 400 mV was applied across the electrodes 11, 12, and the flow of electric current across the electrodes 11, 12 was measured. The resistance value was calculated from the applied voltage value and the measured current value.

The resistance change of the sample device was tested. Specifically, while making the resistance measurement across the electrodes 11, 12 in the sample device, a voltage application under a first condition and a subsequent voltage application under a second condition were performed repeatedly on the sample device. Under the first condition, the electrode 11 served as a negative electrode, the electrode 12 served as a positive electrode, and the voltage application across the electrodes 11, 12 was made with a pulse voltage which had a pulse strength of 5V and a pulse width of 20 nsec. The voltage application under the first condition caused the sample device to undergo an upward resistance change. Under the second condition, the electrode 11 served as a positive electrode, the electrode 12 served as a negative electrode, and the voltage application across the electrodes 11, 12 was made with a pulse voltage which had a pulse strength of 5 V and a pulse width of 20 nsec. The voltage application under the second condition caused the sample device to undergo a downward resistance change.

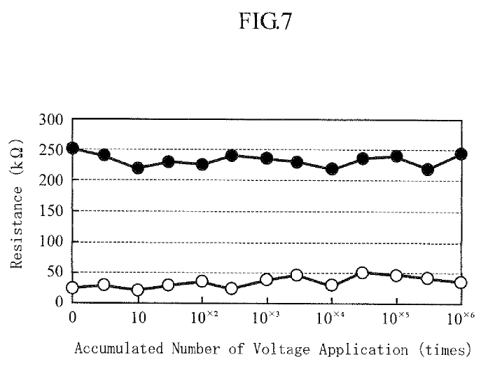

FIG. 7 is a graph illustrating some resistance values measured successively on the sample device during the above-described resistance change test. In the graph of FIG. 7, the horizontal axis indicates the accumulated number (times) of voltage application in common logarithm scale, and the vertical axis indicates the resistance value (kΩ). First plots () indicate resistance values measured in the high resistance state, and second plots (∘) indicate resistance values measured in the low resistance state.

As indicated in the graph in FIG. 7, the sample device exhibited changes in its resistance. In the illustrated resistance switching, there was a relatively large difference between the resistance values in the high resistance state and in the low resistance state, and the difference of the resistance values did not decrease through repeating the resistance switching a number of times.

In place of the oxygen-defective Ti[+3, +4]O₂ used for making the hole conductive layer 3, use was made of other materials such as oxygen-defective Cr₂[+2, +3]O₃, oxygen-defective Cr[+3, +4]O₂, oxygen-defective Mn[+3, +4]O₂, oxygen-defective Fe₂[+2, +3]O₃, oxygen-defective Co₂[+2, +3]O₃, oxygen-defective Zn[+2, +4]O₂, oxygen-defective Ru[+3, +4]O₂, oxygen-defective Ru₂[+4, +5]O₅, oxygen-defective Pd₂[+2, +3]O₃, oxygen-defective Ta[+3, +4]O₂, oxygen-defective Ta₂[+4, +5]O₅, and oxygen-defective Ce[+3, +4]O₂. With the use of these materials, sample devices (each contained a greater amount of low-valence-state second chemical elements than high-valence-state second chemical elements) were made and tested. In all cases, resistance switching was observed.

1. A resistance variable device having a laminated structure comprising:
a first electrode;
a second electrode; and
a hole conductive layer between the first electrode and the second electrode;
wherein the hole conductive layer gives anions to the second electrode for changing a state of the hole conductive layer from a reference electric field state to a positive electric field state, and the hole conductive layer receives anions from the second electrode for changing the state of the hole conductive layer from the positive electric field state to the reference electric field state.

2. The resistance variable device according to claim 1, wherein the hole conductive layer is made of a binary substance containing a first element for producing the anions and a second element capable of existing stably in two states of different valences.

3. The resistance variable device according to claim 2, wherein (rₘ−rₙ)/rₘ≦0.15 is satisfied, where rₘ is an ionic radius of an m-valence ion of the second element, and rₙ is an ionic radius of an n-valence ion of the second element (n>m).

4. The resistance variable device according to any one of claims 1-3, wherein the hole conductive layer is made of one of oxygen-defective Ti[+3, +4]O₂, oxygen-defective Cr₂[+2, +3]O₃, oxygen-defective Cr[+3, +4]O₂, oxygen-defective Mn[+3, +4]O₂, oxygen-defective Fe₂[+2, +3]O₃, oxygen-defective Co₂[+2, +3]O₃, oxygen-defective Zn[+2, +4]O₂, oxygen-defective Ru[+3, +4]O₂, oxygen-defective Ru₂[+4, +5]O₅, oxygen-defective Pd₂[+2, +3]O₃, oxygen-defective Ta[+3, +4]O₂, oxygen-defective Ta₂[+4, +5]O₅ and oxygen-defective Ce[+3, +4]O₂.

5. A resistance variable device having a laminated structure comprising:
a first electrode;
a second electrode; and
an electron conductive layer between the first electrode and the second electrode;
wherein the electron conductive layer gives cations to the second electrode for changing a state of the electrode conductive layer from a reference electric field state to a negative electric field state, and the electron conductive layer receives cations from the second electrode for changing the state of the electron conductive layer from the negative electric field state to the reference electric field state.

6. The resistance variable device according to claim 5, wherein the electron conductive layer is made of a binary substance containing a first element for producing the cations and a second element capable of existing stably in two states of different valences.

7. The resistance variable device according to claim 6, wherein (rₘ−rₙ)/rₘ≦0.15 is satisfied, where rₘ is an ionic radius of an m-valence ion of the second element, and rₙ is an ionic radius of an n-valence ion of the second element (n>m).

8. The resistance variable device according to any one of claims 5-7, wherein the electron conductive layer is made of one of silver-defective Ag₂S, silver-defective AgI and silver-defective AgBr.
